(19) United States
(12) Patent Application Publication
(10) Pub. No.: US 2015/0170754 A1
(43) Pub. Date: Jun. 18, 2015

(54) Mitigating Inter-Cell Interference

(71) Applicant: Empire Technology Development LLC, Wilimington, DE (US)

(72) Inventor: Xudong Ma, Monterey Park, CA (US)

(73) Assignee: Empire Technology Development LLC, Wilmington, DE (US)

(21) Appl. No.: 13/879,713

(22) PCT Filed: Jan. 17, 2013
(86) PCT No.: PCT/US13/21835

§ 371 Date: Apr. 16, 2013

(51) Int. Cl. G11C 16/34; G06F 12/02

(52) U.S. Cl. CPC G11C 16/3427; G06F 12/0246; G06F 2212/7208

(57) ABSTRACT

Technologies are generally described herein for mitigating inter-cell interference. In some examples, data to be stored in a memory device may be obtained. The memory device may include word lines having memory cells. A first portion of the data can be written to a first group of the word lines, and a second portion of the data can be written to a second group of the word lines.

### BACKGROUND

Unless otherwise indicated herein, the materials described in this section are not prior art to the claims in this application and are not admitted to be prior art by inclusion in this section.

In an effort to increase storage capacity of flash memory devices, the flash memory devices have been scaled down to achieve higher storage densities. One challenge to further scaling down the flash memory devices is inter-cell interference due to small distances between flash memory cells. Because concerns driving the scaling down of flash memory devices may override concerns regarding inter-cell interference, various models have been developed for addressing inter-cell interference.

Because flash memory cells are sometimes laid out in a grid pattern, calculating the inter-cell interference experienced at a particular cell may require solving a complex problem. In particular, determining two-dimensional inter-cell interference in a flash memory device may require solution of an NP-hard problem, and therefore use of these models may be unrealistic and/or may not be useful.

### SUMMARY

The present disclosure generally describes concepts and technologies for mitigating inter-cell interference. According to various implementations of the concepts and technologies disclosed herein, data is obtained at a computing device configured to execute a controller for managing writing data to and reading data from a data storage device such as a flash memory, a phase change memory device, and/or other types of nonvolatile memory devices (hereinafter referred to as “memory devices”). The controller can be configured to divide the data into two or more data portions, and to designate two or more groups of word lines of the memory.

The computing device can be configured to write a first portion of the data to a first group of word lines and to write a second portion of the data to a second group of the word lines. According to various embodiments, the programming and/or writing of the groups of word lines may be independent and may not require any consideration of writing of other word lines. The computing device also can be configured to read data from the first group of word lines independently without considering interference from adjacent word lines because the word lines of the first group can be written after the second group of word lines are written. The computing device also can be configured to estimate interference at the second group of word lines, to read the second group of word lines, and to cancel interference in accordance with the estimated interference. As such, the second group of word lines can be read by the computing device dependently.

According to one aspect, a method for accessing a memory device is disclosed. Data to be stored in the memory device can be obtained. The memory device can include word lines having memory cells. A first portion of the data can be written to a first group of the word lines, and a second portion of the data can be written to a second group of the word lines.

According to some embodiments, the first group of the word lines can include at least two odd-indexed word lines of the memory device. The second group of the word lines can include at least two even-indexed word lines of the memory device. The method further can include reading the data from the memory device. Reading the data can include reading the second portion of the data from the second group of the word lines and reading the first portion of the data from the first group of the word lines. Reading the first portion of the data further can include estimating an inter-cell interference between the first group of the word lines and the second group of the word lines, and cancelling the inter-cell interference when reading the first group of the word lines. In some embodiments, cancelling the inter-cell interference can include cancelling the inter-cell interference using a model for inter-symbol interference. In some other embodiments, cancelling the inter-cell interference can include determining threshold voltages of memory cells of the first group of the word lines, and subtracting an estimated interference voltage from respective threshold voltages of the memory cells of the first group of the word lines.

According to another aspect, a computer readable medium is disclosed. The computer readable medium can include computer executable instructions that, when executed by a computer, cause the computer to obtain data to be stored in a memory device. The memory device can include word lines having memory cells. The computer executable instructions can further cause the computer to write a first portion of the data to a first group of the word lines, and write a second portion of the data to a second group of the word lines.

According to some embodiments, the first group of the word lines can include at least two odd-indexed word lines of the memory device, and the second group of the word lines can include at least two even-indexed word lines of the memory device. The first group of the word lines and the second group of the word lines can be written independently. In some embodiments, to read the data from the memory device, the computer executable instructions further can cause the computer to read the second portion of the data from the second group of the word lines, and read the first portion of the data from the first group of the word lines.

According to some embodiments, to read the first portion of the data, the computer executable instructions, when executed by the computer, can further cause the computer to estimate an inter-cell interference between the first group of the word lines and the second group of the word lines, and cancel the inter-cell interference when reading the first group of the word lines. To cancel the inter-cell interference, the computer executable instructions, when executed by the computer, can further cause the computer to cancel the inter-cell interference using a model for inter-symbol interference. To cancel the inter-cell interference, the computer executable instructions, when executed by the computer, can further cause the computer to determine threshold voltages of memory cells of the first group of the word lines, and subtract an estimated interference voltage from respective threshold voltages of the memory cells of the first group of the word lines. In some embodiments, the first group of the word lines and the second group of the word lines can be written independently, the second group of the word lines can be read independently, and the first group of the words lines can be read dependently.

According to another aspect, a computing device is disclosed. The computing device can include a memory device including word lines having memory cells and a processor coupled to the memory device. The processor can be configured to execute computer executable instructions to obtain data to be stored in the memory device, write a first portion of the data to a first group of the word lines, and write a second portion of the data to a second group of the word lines.

According to some embodiments, the processor can be further configured to execute the computer executable instructions to read the second portion of the data from the second group of the word lines, and read the first portion of the data from the first group of the word lines. The processor can be further configured to execute the computer executable instructions to estimate an inter-cell interference between the first group of the word lines and the second group of the word lines, and cancel the inter-cell interference when reading the first group of the word lines. To cancel the inter-cell interference, the computer executable instructions further can cause the processor to cancel the inter-cell interference using a model for inter-symbol interference.

According to some embodiments, the processor can be further configured to execute the computer executable instructions to determine threshold voltages of memory cells of the first group of the word lines, and subtract an estimated interference voltage from respective threshold voltages of the memory cells of the first group of the word lines. The first group of the word lines can include at least two odd-indexed word lines of the memory device, and the second group of the word lines can include at least two even-indexed word lines of the memory device. In some embodiments, each word line of the first group of the word lines can be offset from a subsequent word line of the first group of the word lines by a single word line. In some other embodiments, each word line of the first group of the word lines can be offset from a subsequent word line of the first group of the word lines by two or more word lines.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 is a block diagram illustrating an operating environment for various embodiments of the concepts and technologies disclosed herein for mitigating inter-cell interference;

FIG. 2 is a line diagram illustrating an example memory device for various embodiments of the concepts and technologies disclosed herein for mitigating inter-cell interference;

FIG. 3 is a flow diagram illustrating an example process for writing data to a data storage device;

FIG. 4 is a flow diagram illustrating an example process for reading data from a data storage device;

FIG. 5 is a block diagram illustrating an example computer capable of mitigating inter-cell interference; and

FIG. 6 is a schematic diagram illustrating computer program products for mitigating inter-cell interference,

all arranged according to at least some embodiments presented herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the FIGURES, can be arranged, substituted, combined, separated, and designed in a wide variety of different configurations, all of which are explicitly contemplated herein.

This disclosure is generally drawn, inter alia, to technologies for mitigating inter-cell interference. In an illustrative example, a computing device can be configured to execute a controller, for example, as part of an operating system, as an executable program, and/or as another type of software or hardware. The controller can be configured to manage writing data to and reading data from a data storage device of the computing device such as, for example, a flash memory or other memory device that can include cells arranged in a number of word lines. The controller can be configured to divide the obtained data into two or more data portions, and to designate two or more groups of the word lines. Each of the groups of word lines can include alternating word lines. Thus, in some embodiments, an empty word line may be provided between each word line of a group of word lines.

The computing device also can be configured to write a first portion of the data to a first group of the word lines, and to write a second portion of the data to a second group of the word lines. According to various embodiments, the programming and/or writing of the groups of word lines may be independent and may not require any consideration of writing of other word lines since adjacent word lines may not be simultaneously written. The computing device also can be configured to read data from the second group of word lines independently, i.e., without considering interference from adjacent word lines because the word lines of the second group can be written after the first group of word lines are written. The computing device also can be configured to estimate interference at the first group of word lines, to read the first group of word lines, and to cancel interference in accordance with the estimated interference. As such, the first group of word lines can be read by the computing device dependently. These and other aspects of systems and methods for mitigating inter-cell interference will be described in more detail herein.

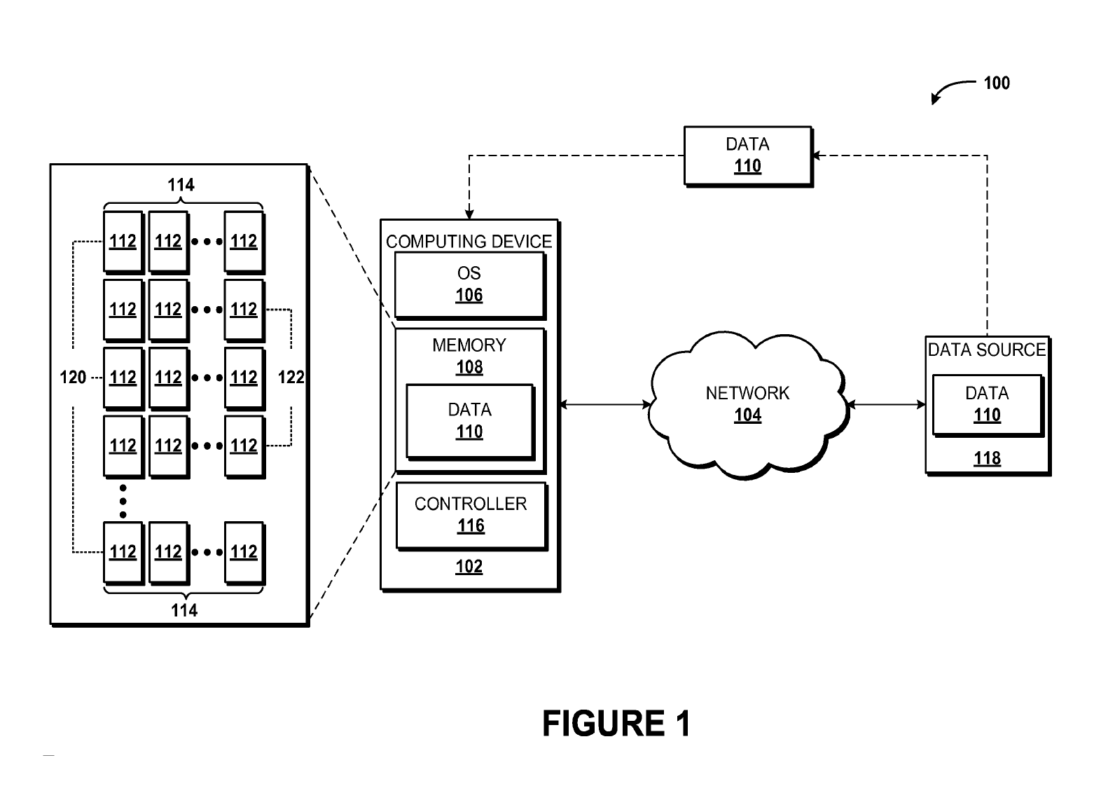

FIG. 1 is a block diagram illustrating an operating environment 100 for various embodiments of the concepts and technologies disclosed herein for mitigating inter-cell interference, arranged in accordance with at least some embodiments presented herein. The operating environment 100 shown in FIG. 1 includes a computing device 102. In some embodiments, the computing device 102 operates as a part of and/or in communication with a communications network (“network”) 104, though this is not necessarily the case. According to various embodiments, the functionality of the computing device 102 can be provided by a personal computer (“PC”) such as a desktop computer, a tablet computer, and/or a laptop computer. In other embodiments, the functionality of the computing device 102 can be provided by other types of computing systems including, but not limited to, server computers, handheld computers, netbook computers, embedded computer systems, personal digital assistants, mobile telephones, smart phones, other computing devices, or the like.

The computing device 102 can be configured to execute an operating system 106 and one or more application programs (not illustrated). The operating system 106 can include a computer program for controlling the operation of the computing device 102. The application programs can include various executable programs configured to execute on top of the operating system 106 to provide functionality associated with the computing device 102. For example, the application programs can include programs for providing various functions associated with the computing device 102 such as, for example, web browsers, messaging applications, productivity software, and/or other applications. It should be understood that these embodiments are illustrative, and should not be construed as being limiting in any way.

The computing device 102 also can include a data storage device (“memory”) 108. The functionality of the memory 108 can be provided by one or more volatile and/or non-volatile memory devices including, but not limited to, flash memory devices, phase-change memory devices, hard disk drives, and/or other memory storage devices. For purposes of illustrating and describing various embodiments of the concepts and technologies described herein, the memory 108 is referred to herein as including a flash memory device or other memory device. Because the memory 108 can include other types of data storage devices, it should be understood that this embodiment is illustrative, and should not be construed as being limiting in any way.

The computing device 102 can be configured to store data 110 in the memory 108. In some embodiments, the computing device 102 can be configured to store the data 110 in the memory 108 by altering voltages of one or more memory cells (“cells”) 112 of the memory 108. Various implementations of the memory 108 can include hundreds, thousands, or even millions of cells 112. The cells 112 can be arranged in a grid structure including various rows and/or columns. A particular row of the cells 112 may correspond to a word line 114, and a memory 108 can include hundreds, thousands, or even millions of word lines 114. The arrangement of cells 112 and/or word lines 114 in memory devices will not be further described herein.

According to various embodiments of the concepts and technologies described herein, the computing device 102 can be configured to include, to execute, and/or to access a controller 116 that can be configured to manage various processes described herein for writing and/or reading the data 110 to and/or from the memory 108. According to some embodiments of the concepts and technologies described herein, the controller 116 can be provided by a hardware controller. According to some other embodiments of the concepts and technologies described herein, the controller 116 can be provided by a software application or module executed by the computing device 102. According to some other embodiments, the controller 116 can be provided as a part of the operating system 106.

For purposes of describing and illustrating the concepts and technologies described herein for mitigating inter-cell interference, the controller 116 is described herein as a software module executed by the computing device 102 as part of the operating system 106 or as a separate application program. In light of the above variations described above, it should be understood that this embodiment is illustrative, and should not be construed as being limiting in any way. The functionality of the controller 116 is described in further detail below.

The computing device 102 can be configured to access and/or receive the data 110 from various sources. In some embodiments, the data 110 can be stored in the memory 108 and/or in other data storage devices associated with and/or accessible by the computing device 102. In some other embodiments, the data 110 can be obtained from a data source 118 that can be configured to operate as a part of and/or in communication with the network 104. According to various implementations, the functionality of the data source 118 can be provided by a network hard drive, a server computer, a data store, and/or other real or virtual devices.

According to various embodiments, the computing device 102 can be configured to receive, access, and/or otherwise obtain the data 110. Via execution of the controller 116, the computing device 102 can divide the data 110 into one or more data portions that include parts or portions (“portions”) of the data 110. In some contemplated embodiments, the computing device 102 can be configured to divide the data 110 into two portions. In some other embodiments, the computing device 102 can be configured to divide the data 110 into more than two portions. The designation of the number of portions into which the data 110 is to be divided may be based upon user settings, device settings, hardware configurations, and/or other considerations. Because the concepts and technologies described herein can include dividing the data 110 into almost any number of portions, it should be understood that these embodiments are illustrative, and should not be construed as being limiting in any way.

The computing device 102 also can be configured to execute the controller 116 to identify and/or designate two or more groups of the word lines 114. In one contemplated embodiment, illustrated and described in FIG. 1, the two or more groups of the word lines 114 can include a first word line group 120 and a second word line group 122. In the illustrated embodiment, the first word line group 120 can include odd-indexed word lines 114 of the memory 108, and the second word line group 122 can include even-indexed word lines 114 of the memory 108. As such, the first word line group 120 can include every other word line 114 of the memory 108 beginning with a first odd-indexed word line 114. Thus, the first word line group 120 may include, for example, word line numbers 1, 3, 5, . . . , etc., until a last odd-indexed word line 114, word line number n.

Similarly, the second word line group 122 can include every other word line 114 of the memory 108 beginning with a first even-indexed word line 114. Thus, the second word line group 122 can include, for example, word line numbers 2, 4, 6, . . . , etc., until a last even-indexed word line 114. It should be understood that this embodiment is illustrative, and should not be construed as being limiting in any way. The designation of a number of groups of the word lines 114 also can be based upon user settings, device settings, hardware configurations, and/or other considerations. If three groups of the word lines 114 are designated by the controller 116, it can be appreciated that every third word line 114 may be in a particular group. As such, it should be understood that these embodiments are illustrative, and should not be construed as being limiting in any way.

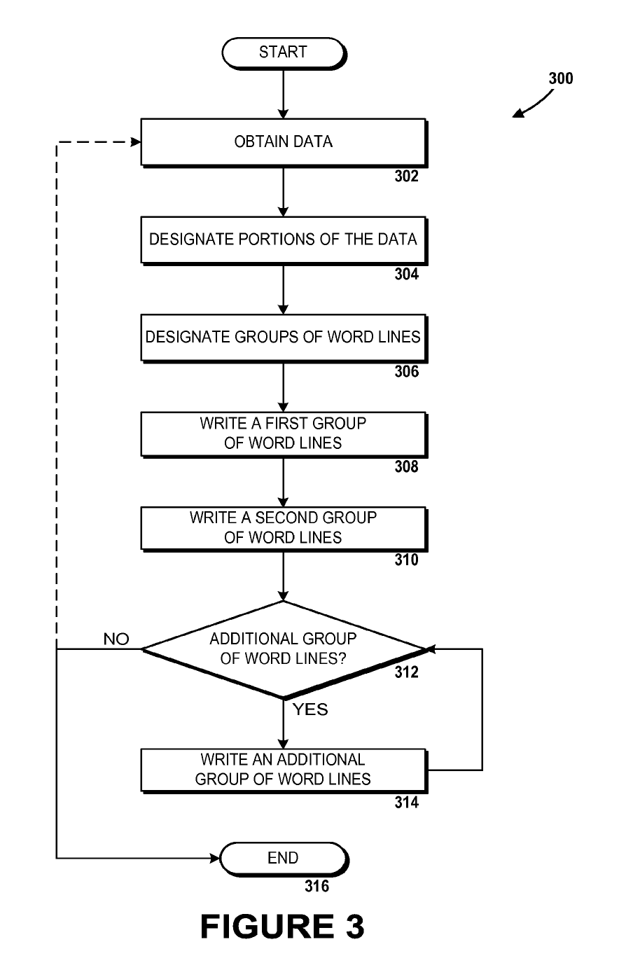

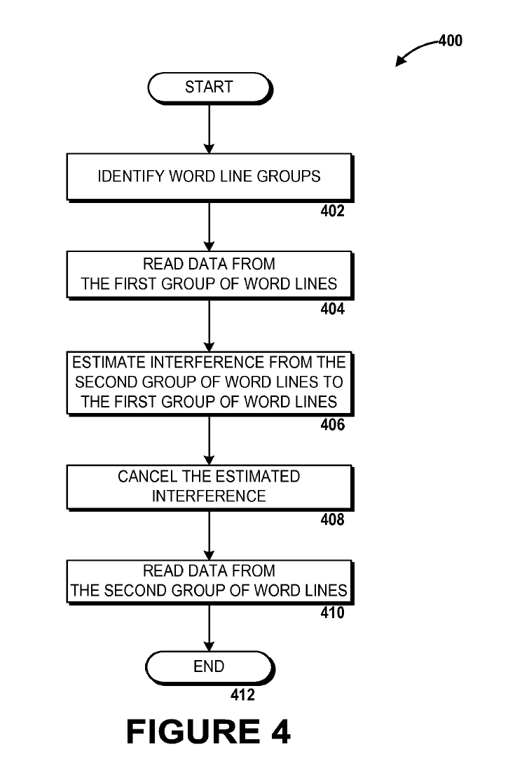

As will be explained below in more detail, particularly with reference to FIGS. 3-4, the computing device 102 can be configured to execute the controller 116 to write the two or more groups of the word lines 114 independently of one another. Similarly, the computing device 102 can be configured to execute the controller 116 to read at least one of the groups of word lines 114 independently of another group of word lines 114. The computing device 102 can be configured to execute the controller 116 to read one or more of the groups of word lines 114 dependently, wherein the controller 116 can consider interference between a particular group of the word lines 114 and another group of the word lines 114.

With reference now to an embodiment such as that illustrated in FIG. 1, writing and reading the word lines 114 using two groups of word lines 114 will be briefly described. As noted above, the computing device 102 can be configured to execute the controller 116 to divide the data 110 into two portions, namely a first portion of the data 110 and a second portion of the data 110. Similarly, the computing device 102 can be configured to execute the controller 116 to designate two groups of the word lines 114, namely the first word line group 120 and the second word line group 122. It should be understood that the word line groups can be known for a particular memory 108, and that as such the designation of these word line groups may not be necessary for a particular read or write process.

During writing, the computing device 102 can be configured to write a first portion of the data 110 to the first word line group 120. After writing the first portion of the data 110 to the first group of the word lines 114, the computing device 102 can be configured to begin writing the second portion of the data 110 to the second word line group 122. By delaying writing of the second portion of the data 110 until after the first portion of the data 110 is written, and by writing alternating word lines 114 instead of adjacent word lines 114, the computing device 102 can be configured to reduce or even eliminate inter-cell interference at cells 112 of the second word line group 120. In particular, the cells 112 of the first word line group 120 may be written with only empty cells 112 of the second word line group adjacent the cells 112 of the second word line group 122. As such, it can be appreciated that the computing device 102 can be configured to write the first portion of the data 110 to the cells 112 of the first word line group 120 independently without consideration of charges of the cells 112 of the second word line group 122.

The cells 112 of the first word line group 120, however, may experience or be subjected to some inter-cell interference during writing of the cells 112 of the second word line group 122. In particular, because the cells 112 of the first word line group 120 can be written before the cells 112 of the second word line group 122 are written, charges of the cells 112 of the first line group 120 may change or otherwise be affected when the cells 112 of the second word line group 122 are written by the computing device 102. As such, charges of the cells 112 of the first word line group 122 may be affected by the charges of the cells 112 of the second word line group 122. Although the charges of the cells 112 of the first word line group 122 may be affected by or during writing of the charges to the cells 112 of the second word line group 120, it should be appreciated that the computing device 102 can be configured to write the second portion of the data 110 to the cells 112 of the second word line group 122 independently, without consideration of the charges of the first word line group 120. As will be explained below in more detail, the computing device 102 can be configured to consider the interference experienced at the first word line group 120 during writing of the second word line group 122 when reading from the first word line group 120.

During reading of the data 110 from the memory 108, the computing device 102 can be configured read the data 110 from the second word line group 122 independently because the cells 112 of the second word line group 122 are written after the cells 112 of the first word line group 120. For example, if a program-and-verify approach is used for writing the memory cells 112, then the latter written memory cells 112 may experience no interference or little interference from the prior written memory cells 112. As such, the computing device 102 can be configured to determine the values of the cells 112 of the second word line group 122 without considering inter-cell interference. As noted above, the cells 112 of the first word line group 120 may be written to the memory 108 before the cells 112 of the second word line group 122 have been written. As such, the cells 112 of the first word line group 120 may experience interference from adjacent word lines 114 during writing of the cells 112 of the adjacent word lines 114. Of course, the cells 112 of a particular word line 114 may interfere with one another, but the correction of this interference can be effected by applying a model for inter-symbol interference, which may be a known property for a given memory 108.

During reading of the data 110 from the memory 108, the computing device 102 can be configured read the data 110 from the first word line group 120 dependently. In some embodiments, the computing device 102 can be configured to determine the values of the cells 112 of the first word line group 120 by considering inter-cell interference from the word lines 114 of the second word line group 122. In particular, the computing device 102 can be configured to execute the controller 116 to estimate an interference from the second word line group 122 to the first word line group 120. The computing device 102 can be configured to execute the controller 116 to estimate this interference based upon various known properties of the memory 108. Because the first word line group 120 can include alternating word lines 114, the estimation of the interference experienced by cells 112 of the first word line group 120 may again include application of a model for inter-symbol interference that may be known for the memory 108. Thus, estimating the interference experienced by the cells 112 of the first word line group 120 may not be an NP-hard problem, as may be the case if the word lines 114 of the memory 108 were instead written in sequential order.

As such, the computing device 102 can be configured to read the data 110 from the cells 112 of the first word line group 120, cancel the interference based upon the estimated interference, and determine the values of the cells 112 of the first word line group 120 based upon the values and the cancelled interference. In some embodiments, the computing device 102 can be configured to determine voltages of the cells 112 of the first word line group 120 and adjust the voltages based upon the estimated interference.

As noted above, the cells 112 of the second word line group 122 can be written after the cells 112 of the first word line group 120 are written. As such, it can be appreciated that the computing device 102 can be configured to read the second portion of the data 110 from the cells 112 of the second word line group 122 independently without taking into account the estimated inter-cell interference between the first word line group 120 and the second word line group 122, and to read the first portion of the data 110 from the cells 112 of the first word line group 122 dependently by taking into account the estimated inter-cell interference between the first word line group 120 and the second word line group 122. It should be understood that these embodiments are illustrative, and should not be construed as being limiting in any way.

FIG. 1 illustrates one computing device 102, one memory 108, one controller 116, and one data source 118. It should be understood, however, that some implementations of the operating environment 100 include multiple computing devices 102, multiple memories 108, multiple controllers 116, and/or zero or multiple data sources 118. Thus, the illustrated embodiment of the operating environment 100 should be understood as being illustrative of one embodiment thereof and should not be construed as being limiting in any way.

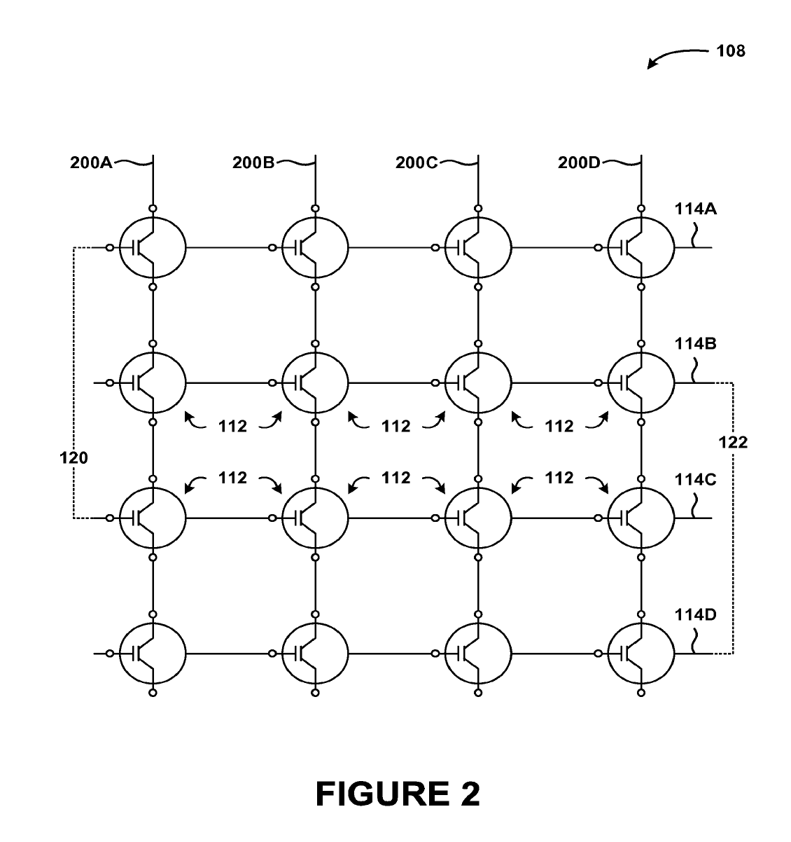

Turning now to FIG. 2, a line diagram illustrating an example memory device for various embodiments of the concepts and technologies disclosed herein for mitigating inter-cell interference, arranged according to at least some embodiments presented herein, will be described. FIG. 2 illustrates an example memory device such as the memory 108 illustrated and described herein. It should be understood that only a portion of the memory 108 is shown in FIG. 2.

The memory 108 can include word lines 114A-D, which can correspond to particular examples of the word lines 114 described herein, particularly with reference to FIG. 1 above. Additionally, the cells 112 of the memory 108 shown in FIG. 2 correspond to one contemplated example of the cells 112 and therefore should not be construed as being limiting in any way. Additionally shown in FIG. 2 are bit lines 200A-D (hereinafter collectively and/or generically referred to as “bit lines 200”).

As shown in FIG. 2, the word lines 114A and 114C can be included in and/or can correspond to the first word line group 120 described herein. Similarly, the word lines 114B and 114D can be included in and/or can correspond to the second word line group 122. Because additional and/or alternative word lines 114 may be included in the first word line group 120 and/or the second world line group 122, and because alternative groupings of the word lines 114 in the first word line group 120 and the second world line group 122 are contemplated and are possible, it should be understood that this embodiment is illustrative, and should not be construed as being limiting in any way.

Turning now to FIG. 3, a flow diagram illustrating an example process 300 for writing data to a data storage device, arranged according to at least some embodiments presented herein, will be described. It should be understood that the operations of the processes described herein are not necessarily presented in any particular order and that performance of some or all of the operations in an alternative order(s) is possible and is contemplated. The operations have been presented in the demonstrated order for ease of description and illustration. Operations may be added, omitted, and/or performed simultaneously, without departing from the scope of the appended claims.

It also should be understood that the illustrated processes can be ended at any time and need not be performed in its entirety. Some or all operations of the processes, and/or substantially equivalent operations, can be performed by execution of computer-readable instructions included on a computer storage media, as defined herein. The term “computer-readable instructions,” and variants thereof, as used in the description and claims, is used expansively herein to include routines, applications, application modules, program modules, programs, components, data structures, algorithms, or the like. Computer-readable instructions can be implemented on various system configurations, including single-processor or multiprocessor systems, minicomputers, mainframe computers, personal computers, hand-held computing devices, microprocessor-based, programmable consumer electronics, combinations thereof, or the like.

For purposes of illustrating and describing the concepts of the present disclosure, the process 300 is described as being performed by the computing device 102. It should be understood that this embodiment is illustrative, and should not be viewed as being limiting in any way. Furthermore, as explained above with reference to FIG. 1, the computing device 102 can be configured to execute one or more applications, program modules, or other instructions including, but not limited to, the controller 116 to provide the functionality described herein.

The process 300 may begin at block 302 (OBTAIN DATA), wherein the computing device 102 can be configured to obtain the data 110. As described above with reference to FIG. 1, the computing device 102 can be configured to obtain the data 110 from a variety of sources. In particular, the computing device 102 may be configured to obtain the data 110 by accessing a local or remote data storage device such as, for example, the memory 108, a hard disk drive, an external data storage device, a remote server computer such as the source 118, and/or other data storage devices. Block 302 may be followed by block 304.

At block 304 (DESIGNATE PORTIONS OF THE DATA), the computing device 102 can be configured to designate one or more portions of the data 110. As explained above, the computing device 102 can be configured to divide the data 110 into a determined or designated number of portions of the data 110. In some embodiments, the computing device 102 can be configured to divide the data 110 into two portions of the data 110, a first portion of the data and a second portion of the data. In some other embodiments, the computing device 102 can be configured to divide the data 110 into three or more portions. The computing device 102 can be configured to designate the portions of the data 110 based, at least partially, upon user settings, hardware settings, data storage device characteristics, software or hardware controls, or other considerations. In block 304, the computing device 102 can designate portions of the data 110 in accordance with a determined number of data portions. Block 304 may be followed by block 306.

At block 306 (DESIGNATE GROUPS OF WORD LINES), the computing device 102 can be configured to designate one or more groups of the word lines 114. As explained above with reference to FIG. 1, the groups of the word lines 114 can, but do not necessarily, include the first word line group 120 and the second word line group 122. As explained above with reference to FIG. 1, the first word line group 120 can include even-indexed word lines 114 of the memory 108 and the second word line group 122 can include odd-indexed word lines 114 of the memory 108. This embodiment is illustrative and should not be construed as being limiting in any way.

Similarly, as explained above with reference to block 304, the computing device 102 can be configured to designate more than two groups of the word lines 114. According to various embodiments, the computing device can designate a number of groups of the word lines 114 based upon a number of portions of the data determined in block 304. Thus, for example, if the computing device 102 determines that the data 110 is to be divided into two portions, the computing device 102 can similarly determine that the word lines 114 are to be divided into two groups of the word lines 114. It should be understood that this embodiment is illustrative, and should not be construed as being limiting in any way.

As noted above, the computing device 102 can be configured to designate the groups of word lines by assigning alternating word lines 114 to groups. As such, a word line group may include alternating word lines 114 of the memory 108, thereby padding or insulating each word line of a word line group with an empty adjacent word line 114. If more than two word line groups are designated, then more than one empty word line 114 may be adjacent each word line 114 of a word line group. As noted above, this arrangement may be used to reduce or even eliminate interference between cells 112 of adjacent word lines 114, which can be used to simplify calculation of estimated interference among cells 112 of the word lines 114. Block 306 may be followed by block 308.

At block 308 (WRITE A FIRST GROUP OF WORD LINES), the computing device 102 can be configured to write a first group of the word lines 114. The computing device 102 can be configured to write a first portion of the data 110 to the first group of word lines 114. As explained above, the computing device 102 can be configured to write alternating word lines 114 of the memory 108. Thus, writing of the first group of word lines may be independent of writing of other word lines 114. Block 308 may be followed by block 310.

At block 310 (WRITE A SECOND GROUP OF WORD LINES), the computing device 102 can be configured to write a second group of the word lines 114. The computing device 102 can be configured to write a second portion of the data 110 to the second group of word lines 114. As explained above, the computing device 102 can be configured to write the second group of word lines 114 independent of writing other word lines 114. Block 310 can be followed by block 312.

At block 312 (ADDITIONAL GROUP OF WORD LINES?), the computing device 102 can be configured to determine if additional groups of word lines 114 remain to be written. As noted above, the computing device may designate two or more groups of word lines 114. As such, the computing device 102 may be configured to determine, at block 312, if more than two groups of word lines 114 are designated and/or if all word line groups have previously been written. If the computing device 102 determines, at block 312, that an additional group of word lines 114 remains to be written, block 312 can be followed by block 314.

At block 314 (WRITE AN ADDITIONAL GROUP OF WORD LINES), the computing device 102 can be configured to write the additional group of word lines determined to exist at block 312. From block 314, execution of the process 300 can return to block 312, wherein the computing device 102 can be configured to again determine if an additional group of word lines remain to be written. As such, execution of the process 300 by the computing device 102 can, but does not necessarily, pause at or reiterate blocks 312-314 until the computing device 102 determines, in any iteration of block 312, that an additional group of word lines 114 does not remain to be written. If the computing device 102 determines, in any iteration of block 312, that an additional group of word lines does not remain to be written, block 312 can be followed by block 316. At block 316 (END), the computing device 102 can be configured to terminate execution of the process 300. The computing device 102 also may be configured to repeat (e.g., periodically, continuously, or on-demand) the process 300 by returning to block 302 from block 312. Similarly, the computing device 102 may be configured to terminate the process 300 at any time, as noted above.

Turning now to FIG. 4, a flow diagram illustrating an example process 400 for reading data from a data storage device, arranged according to at least some embodiments presented herein, will be described. The process 400 may begin at block 402 (IDENTIFY WORD LINE GROUPS), wherein the computing device 102 may be configured to identify one or more groups of word lines 114 within a data storage device such as the memory 108. It may be appreciated with reference to the process 300 described above with reference to FIG. 3 that the word lines groups can include at least the first word line group 120 and the second word line group 122, though this is not necessarily the case. Similarly, it should be understood that the identification of the word line groups may not be necessary for a particular read process, as the word line groups may be a known property for a memory 108 or other data storage device. Block 402 may be followed by block 404.

At block 404 (READ DATA FROM THE FIRST GROUP OF WORD LINES), the computing device 102 can be configured to read data from the first group of word lines 114. The computing device 102 can be configured to access cells 112 of the first group of word lines 114 and determine voltages of those cells 112. Because other reading processes are possible, it should be understood that this embodiment is illustrative, and should not be construed as being limiting in any way. As explained above, some embodiments of the computing device 102 can be configured to read the cells 112 of the first word line group 120 dependently by considering interference experienced at the cells 112 of the first word line group 120 that may result from writing of the cells 112 of the second word line group 122. Block 404 may be followed by block 406.

At block 406 (ESTIMATE INTERFERENCE FROM THE SECOND GROUP OF WORD LINES TO THE FIRST GROUP OF WORD LINES), the computing device 102 can be configured to estimate an inter-cell interference from the second group of the word lines 114 to a first group of the word lines 114 such as, for example, the first word line group 120. As noted above, the cells 112 of the first word line group 120 may be written before the cells 112 of the second word line group 122 and/or other adjacent word lines 114 are written. As such, voltages of the cells 112 of the first word line group 120 may be changed during writing of the cells 112 of the second word line group 122. As such, some embodiments of the computing device 102 can be configured to read the cells 112 of the first word line group 120 dependently by considering interference experienced at the cells 112 of the first word line group 120 that may result from writing of the cells 112 of the second word line group 122.

Thus, block 406 illustrates, inter alia, the computing device 102 estimating the experienced interference experienced at the cells 112 of the first word line group 120 during writing of the cells 112 of the second word line group 122. Because the computing device 102 can be configured not to write adjacent word lines 114 simultaneously, the estimation of the interference between word lines 114 can be accomplished by applying a model for inter-symbol interference. Thus, estimation of the interference between word lines 114 of word line groups may be relatively simple and may not be NP-hard as may be the case if adjacent word lines 114 were simultaneously written by the computing device 102. Block 406 may be followed by block 408.

At block 408 (CANCEL THE ESTIMATED INTERFERENCE), the computing device 102 can be configured to cancel the interference estimated at block 406 from the values of the cells 112 read at block 404. In particular, the computing device 102 can be configured to determine threshold voltages of the cells 112 at block 408 and subtract from the determined threshold voltages, an interference voltage estimated at block 406. According to various embodiments, the computing device 102 can cancel the interference at block 408 without solving an NP-hard problem that may result from simultaneously writing adjacent word lines 114 of the memory 108. As such, some embodiments of the concepts and technologies disclosed herein can be used to simplify estimation and/or cancellation of inter-cell interference, thereby effectively mitigating this inter-cell interference. Block 408 may be followed by block 410.

At block 410 (READ DATA FROM THE SECOND GROUP OF WORD LINES), the computing device 102 can be configured to read data from a second group of the word lines 114 such as, for example, the second word line group 122. The computing device 102 can be configured to read the data 110 independently. Thus, the computing device 102 can be configured to determine voltages of the cells 112 of the second word line group 122 without considering interference from neighboring word lines 114 since the word lines 114 of the second word line group 122 can be written after the word lines 114 of the first word line group 120 and/or other adjacent word lines 114 are written. Furthermore, as noted above, the computing device 102 can be configured to correct or cancel inter-cell interference resulting from neighboring cells 112 of a particular word line 114, though this is not separately illustrated in FIG. 4. Block 410 may be followed by block 412.

At block 412 (END), the computing device 102 can be configured to terminate the process 400. The process 400 also may be repeated (e.g., periodically, continuously, or on-demand) or terminate at any time, as noted above. As such, some embodiments of the process 400 can return to block 402 from block 410.

As explained herein, the process 400 illustrates one example embodiment, wherein only two word line groups are read. It should be understood, however, that various contemplated implementations of the concepts and technologies disclosed herein include reading two or more than two word line groups and/or cancelling interference experienced during writing two or more than two word line groups. It can be appreciated from the above description, that a word line group can experience interference from multiple word line groups written after that word line group. Thus, the process 400 can include additional and/or alternative operations for identifying and cancelling interference between word line groups.

In one example, the concepts and technologies disclosed herein can be used to read three word line groups and/or to cancel interference experienced by cells 112 of the three word line groups. In such an example, a first-written word line group can be written first, a second-written word line group can be written second, and a third-written word line group can be written third (or last). It can be appreciated that the cells 112 of the first-written word line group may experience interference during writing of cells 112 of the second-written word line group, as well as during writing of cells 112 of the third-written word line group. Also, it can be appreciated that the cells 112 of the second-written word line group can experience interference during writing of the cells 112 of the third-written word line group. Similarly, as noted above, cells 112 of a particular word line group can experience interference during writing of cells 112 of any number of later-written word line groups.

In the above example of three word line groups, the reading and cancelling of interference can be accomplished as follows. When the computing device 102 reads the first-written word line group, the computing device 102 can be configured to calculate the interference experienced by the cells 112 of the first-written word line group during writing of the cells 112 of both the second-written word line group and the third-written word line group, and to cancel out this interference. Similarly, when the computing device 102 reads the second-written word line group, the computing device 102 can be configured to calculate the interference experienced by the cells 112 of the second-written word line group during writing of the cells 112 of the third-written word line group, and to cancel out this interference. The computing device 102 can be configured to read the cells 112 of the third-written word line group independently as described hereinabove. In some embodiments, the computing device 102 can be configured to read any number of word line groups by extending the above-described approach. It should be understood that this embodiment is illustrative, and should not be construed as being limiting in any way.

It should be understood that while the above description sometimes refers to cells 112 experiencing interference from cells 112, the interference experienced by cells 112 can be experienced due to interference experienced during the writing of the cells 112. In other words, interference at cells 112 as described herein can refer to interference caused during writing of cells 112. While other interference can be experienced by the cells 112, the above-described embodiments can be directed to cancelling the interference experienced during writing. Thus, the above references to interference can refer to interference experienced by prior-written cells 112 during writing of later-written cells 112. It should be understood that this embodiment is illustrative, and should not be construed as being limiting in any way.

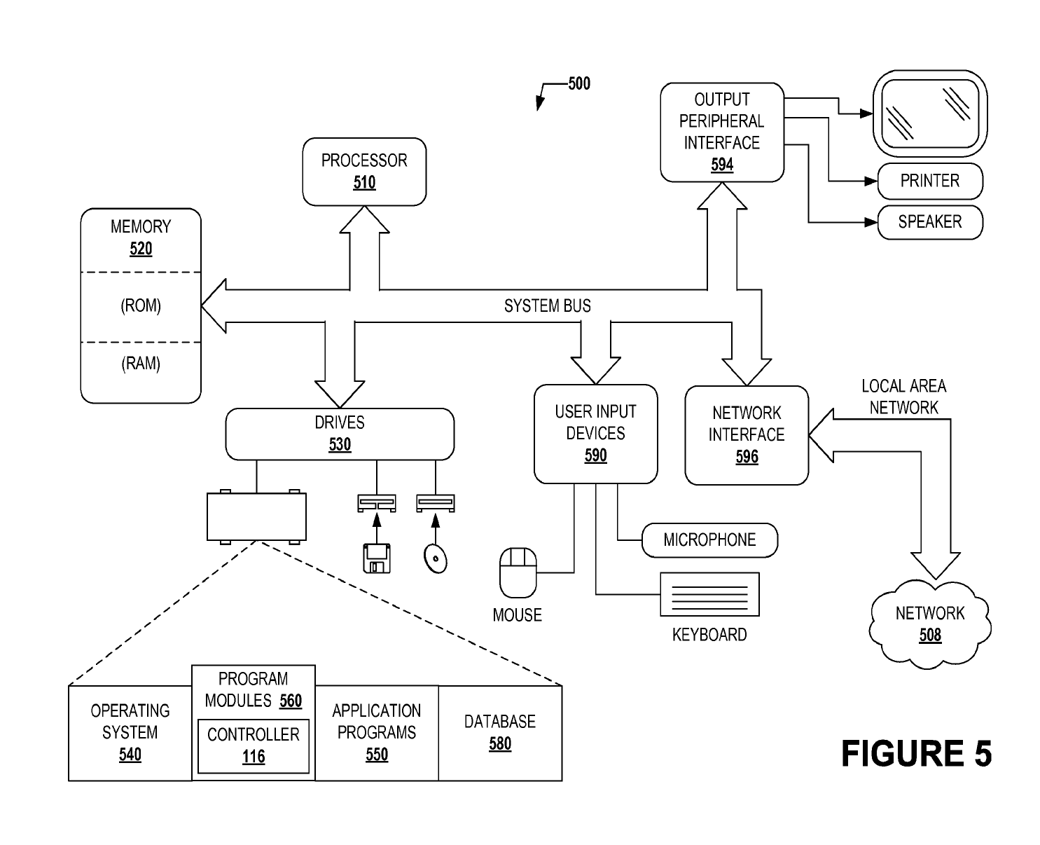

FIG. 5 is a block diagram illustrating an example computer 500 capable of mitigating inter-cell interference arranged according to at least some embodiments presented herein. As depicted, the computer 500 includes a processor 510, a memory 520 and one or more drives 530. The computer 500 may be implemented as a conventional computer system, an embedded control computer, a laptop computer, a server computer, a mobile telephone or smartphone, a set top box (“STB”), a vehicle computing system, or other hardware platform.

The drives 530 and their associated computer storage media, provide storage of computer readable instructions, data structures, program modules and other data for the computer 500. The drives 530 can include an operating system 540, application programs 550, program modules 560, and a database 580. The program modules 560 may include a controller or control module such as the controller 116 described herein. The controller 116 may be adapted to execute either or both of the processes 300 and/or 400 for mitigating inter-cell interference as described in greater detail above (e.g., see previous description with respect to one or more of FIGS. 1-4). The computer 500 further includes user input devices 590 through which a user may enter commands and data. The input devices 590 can include one or more of an electronic digitizer, a microphone, a keyboard and pointing device, commonly referred to as a mouse, trackball or touch pad. Other input devices may include a joystick, game pad, satellite dish, scanner, other devices, or the like.

These and other input devices can be coupled to the processor 510 through a user input interface that is coupled to a system bus, but may be coupled by other interface and bus structures, such as a parallel port, game port or a universal serial bus (“USB”). Computers such as the computer 500 also may include other peripheral output devices such as speakers, printers, displays, and/or other devices, which may be coupled through an output peripheral interface 594 or the like.

The computer 500 may operate in a networked environment using logical connections to one or more computers, such as the data source 118, other remote computers (not illustrated), and/or other devices operating as part of or in communication with a network 508 coupled to a network interface 596. The remote computer may be a personal computer, a server, a router, a network PC, a peer device or other common network node, and can include many or all of the elements described above relative to the computer 500. Networking environments are commonplace in offices, enterprise-wide area networks (“WAN”), local area networks (“LAN”), intranets, and the Internet.

When used in a LAN or WLAN networking environment, the computer 500 may be coupled to the LAN through the network interface 596 or an adapter. When used in a WAN networking environment, the computer 500 typically includes a modem or other means for establishing communications over the WAN, such as the Internet or the network 508. The WAN may include the Internet, the illustrated network 508, various other networks, or any combination thereof. It will be appreciated that other mechanisms of establishing a communications link, ring, mesh, bus, cloud, or network between the computers may be used.

According to some embodiments, the computer 500 may be coupled to a networking environment. The computer 500 may include one or more instances of a physical computer-readable storage medium or media associated with the drives 530 or other storage devices. The system bus may enable the processor 510 to read code and/or data to/from the computer storage media. The media may represent an apparatus in the form of storage elements that are implemented using any suitable technology, including but not limited to semiconductors, magnetic materials, optical media, electrical storage, electrochemical storage, or any other such storage technology. The media may represent components associated with memory 520, whether characterized as RAM, ROM, flash, or other types of volatile or nonvolatile memory technology. The media may also represent secondary storage, whether implemented as the storage drives 530 or otherwise. Hard drive implementations may be characterized as solid state, or may include rotating media storing magnetically-encoded information.

The storage media may include one or more program modules 560. The program modules 560 may include software instructions that, when loaded into the processor 510 and executed, transform a general-purpose computing system into a special-purpose computing system. As detailed throughout this description, the program modules 560 may provide various tools or techniques by which the computer 500 may participate within the overall systems or operating environments using the components, logic flows, and/or data structures discussed herein.

The processor 510 may be constructed from any number of transistors or other circuit elements, which may individually or collectively assume any number of states. More specifically, the processor 510 may operate as a state machine or finite-state machine. Such a machine may be transformed to a second machine, or specific machine by loading executable instructions contained within the program modules 560. These computer-executable instructions may transform the processor 510 by specifying how the processor 510 transitions between states, thereby transforming the transistors or other circuit elements constituting the processor 510 from a first machine to a second machine. The states of either machine may also be transformed by receiving input from the one or more user input devices 590, the network interface 596, other peripherals, other interfaces, or one or more users or other actors. Either machine may also transform states, or various physical characteristics of various output devices such as printers, speakers, video displays, or otherwise.

Encoding the program modules 560 may also transform the physical structure of the storage media. The specific transformation of physical structure may depend on various factors, in different implementations of this description. Examples of such factors may include, but are not limited to: the technology used to implement the storage media, whether the storage media are characterized as primary or secondary storage, or the like. For example, if the storage media are implemented as semiconductor-based memory, the program modules 560 may transform the physical state of the semiconductor memory 520 when the software is encoded therein. For example, the software may transform the state of transistors, capacitors, or other discrete circuit elements constituting the semiconductor memory 520.

As another example, the storage media may be implemented using magnetic or optical technology such as drives 530. In such implementations, the program modules 560 may transform the physical state of magnetic or optical media, when the software is encoded therein. These transformations may include altering the magnetic characteristics of particular locations within given magnetic media. These transformations may also include altering the physical features or characteristics of particular locations within given optical media, to change the optical characteristics of those locations. It should be appreciated that various other transformations of physical media are possible without departing from the scope and spirit of the present description. As used in the claims, the phrase “computer storage medium,” and variations thereof, does not include waves, signals, and/or other transitory and/or intangible communication media, per se.

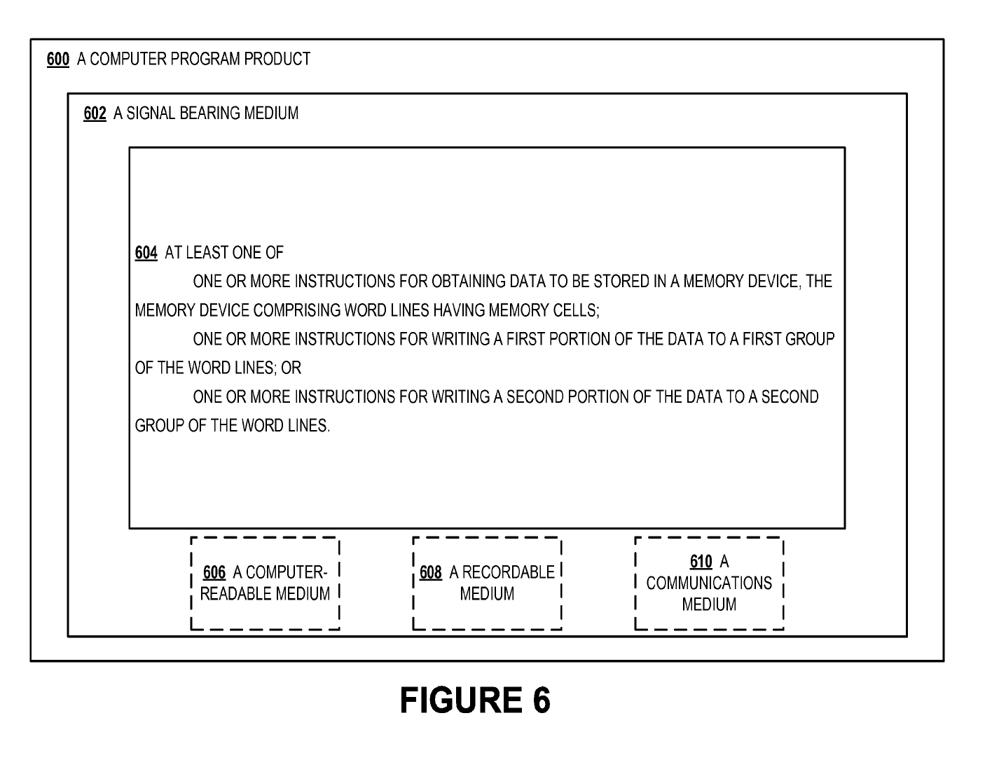

FIG. 6 is a schematic diagram illustrating computer program products 600 for mitigating inter-cell interference arranged according to at least some embodiments presented herein. An illustrative embodiment of the example computer program product 600 is provided using a signal bearing medium 602, and may include at least one instruction 604. The at least one instruction 604 may include: one or more instructions for one or more instructions for obtaining data to be stored in a memory device, the memory device comprising word lines having memory cells; one or more instructions for writing a first portion of the data to a first group of the word lines; or one or more instructions for writing a second portion of the data to a second group of the word lines. In some embodiments, the signal bearing medium 602 of the one or more computer program products 600 include a computer readable medium 606, a recordable medium 608, and/or a communications medium 610.

While the subject matter described herein is presented in the general context of program modules that execute in conjunction with the execution of an operating system and application programs on a computer system, those skilled in the art will recognize that other implementations may be performed in combination with other types of program modules. Generally, program modules include routines, programs, components, data structures, and other types of structures that perform particular tasks or implement particular abstract data types. Moreover, those skilled in the art will appreciate that the subject matter described herein may be practiced with other computer system configurations, including hand-held devices, multi-core processor systems, microprocessor-based or programmable consumer electronics, minicomputers, mainframe computers, or the like.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, compounds, or compositions, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” or the like include the number recited and refer to ranges which can be subsequently broken down into subranges as discussed above. Finally, as will be understood by one skilled in the art, a range includes each individual member. Thus, for example, a group having 1-3 elements refers to groups having 1, 2, or 3 elements. Similarly, a group having 1-5 elements refers to groups having 1, 2, 3, 4, or 5 elements, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A computer-implemented method for accessing a memory device, the method comprising:
obtaining data to be stored in the memory device, the memory device comprising word lines having memory cells;
writing, by a computing device, a first portion of the data to a first group of the word lines; and
writing, by the computing device, a second portion of the data to a second group of the word lines.

2. The method of claim 1, wherein the first group of the word lines comprises at least two odd-indexed word lines of the memory device.

3. The method of claim 2, wherein the second group of the word lines comprises at least two even-indexed word lines of the memory device.

4. The method of claim 1, further comprising reading, by the computing device, the data from the memory device.

5. The method of claim 4, wherein reading the data comprises:
reading, by the computing device, the second portion of the data from the second group of the word lines; and
reading, by the computing device, the first portion of the data from the first group of the word lines.

6. The method of claim 5, wherein reading the second portion of the data further comprises
estimating, by the computing device, an inter-cell interference between the first group of the word lines and the second group of the word lines, and
cancelling, by the computing device, the inter-cell interference when reading the second group of the word lines.

7. The method of claim 6, wherein cancelling the inter-cell interference comprises cancelling, by the computing device, the inter-cell interference using a model for inter-symbol interference.

8. The method of claim 6, wherein cancelling the inter-cell interference comprises
determining, by the computing device, threshold voltages of memory cells of the second group of the word lines, and
subtracting, by the computing device, an estimated interference voltage from respective threshold voltages of the memory cells of the second group of the word lines.

9. A computer readable medium comprising computer executable instructions that, when executed by a computer, cause the computer to:
obtain data to be stored in a memory device, the memory device comprising word lines having memory cells;
write a first portion of the data to a first group of the word lines; and
write a second portion of the data to a second group of the word lines.

10. The computer readable medium of claim 9, wherein the first group of the word lines comprises at least two odd-indexed word lines of the memory device, and wherein the second group of the word lines comprises at least two even-indexed word lines of the memory device.

11. The computer readable medium of claim 9, wherein the first group of the word lines and the second group of the word lines are written independently.

12. The computer readable medium of claim 9, wherein to read the data from the memory device, the computer executable instructions further cause the computer to:
read the second portion of the data from the second group of the word lines; and
read the first portion of the data from the first group of the word lines.

13. The computer readable medium of claim 12, wherein to read the first portion of the data, the computer executable instructions, when executed by the computer, further cause the computer to:
estimate an inter-cell interference between the first group of the word lines and the second group of the word lines; and
cancel the inter-cell interference when reading the second group of the word lines.

14. The computer readable medium of claim 13, wherein to cancel the inter-cell interference, the computer executable instructions, when executed by the computer, further cause the computer to cancel the inter-cell interference using an inter-symbol interference model.

15. The computer readable medium of claim 13, wherein to cancel the inter-cell interference, the computer executable instructions, when executed by the computer, further cause the computer to:
determine threshold voltages of memory cells of the second group of the word lines, and
subtract an estimated interference voltage from respective threshold voltages of the memory cells of the second group of the word lines.

16. The computer readable medium of claim 15, wherein the first group of the word lines and the second group of the word lines are written independently, wherein the first group of the word lines are read independently, and wherein the second group of the words lines are read dependently.

17. A computing device, comprising:
a memory device comprising word lines having memory cells; and
a processor coupled to the memory device and configured to execute computer executable instructions to
obtain data to be stored in the memory device,
write a first portion of the data to a first group of the word lines, and
write a second portion of the data to a second group of the word lines.

18. The computing device of claim 17, wherein the processor is further configured to execute the computer executable instructions to
read the second portion of the data from the second group of the word lines; and
read the first portion of the data from the first group of the word lines.

19. The computing device of claim 18, wherein the processor is further configured to execute the computer executable instructions to:
estimate an inter-cell interference between the first group of the word lines and the second group of the word lines; and
cancel the inter-cell interference when reading the second group of the word lines.

20. The computing device of claim 19, wherein to cancel the inter-cell interference, the computer executable instructions further cause the processor to cancel the inter-cell interference using an inter-symbol interference model.

21. The computing device of claim 20, wherein the processor is further configured to execute the computer executable instructions to:
determine threshold voltages of memory cells of the second group of the word lines, and
subtract an estimated interference voltage from respective threshold voltages of the memory cells of the second group of the word lines.

22. The computing device of claim 17, wherein the first group of the word lines comprises at least two odd-indexed word lines of the memory device, and wherein the second group of the word lines comprises at least two even-indexed word lines of the memory device.

23. The computing device of claim 17, wherein each word line of the first group of the word lines is offset from a subsequent word line of the first group of the word lines by a single word line.

24. The computing device of claim 17, wherein each word line of the first group of the word lines is offset from a subsequent word line of the first group of the word lines by a plurality of word lines.
